(19) United States
(12) Patent Application Publication
(10) Pub. No.: US 2016/0194240 A1
(43) Pub. Date: Jul. 7, 2016

(54) METHOD OF MANUFACTURING PHOTOSENSITIVE GLASS SUBSTRATE

(71) Applicant: HOYA CORPORATION, Shinjuku-ku, Tokyo (JP)

(72) Inventor: Takashi FUSHIE, Tokyo (JP)

(73) Assignee: HOYA CORPORATION, Shinjuku-ku, Tokyo (JP)

(21) Appl. No.: 14/911,456

(22) PCT Filed: Aug. 13, 2014
(86) PCT No.: PCT/JP2014/071390

§ 371 Date: Feb. 10, 2016

(30) Foreign Application Priority Data
Aug. 23, 2013 (JP) 2013-173872

(51) Int. Cl. C03C 4/04; G03F 7/38; G03F 7/36; G03F 7/20

(52) U.S. Cl. CPC C03C 4/04; G03F 7/2051; G03F 7/38; G03F 7/36

(57) ABSTRACT

A method of manufacturing a photosensitive glass substrate, including: directly irradiating a plate-like base material composed of a photosensitive glass with an energy beam to form a latent image; crystallizing the latent image by a first heat treatment to obtain a crystallized portion; and dissolving and removing the crystallized portion and applying fine processing thereto, to obtain a photosensitive glass substrate, wherein in the irradiating, an irradiation position of the energy beam is corrected based on a dimensional variation of the photosensitive glass caused by a heat treatment including at least the first heat treatment.

### BACKGROUND

1. Technical Field

The present invention relates to a method of manufacturing a photosensitive glass substrate.

2. Description of Related Art

A photosensitive glass is the glass in which only an exposed portion is crystallized by exposing and applying heat treatment to the glass containing a photosensitive component and a sensitizing component. In the crystallized portion, a dissolving rate to acid is very fast, compared with a non-crystallized portion. Accordingly, by utilizing such a property, selective etching can be applied to the photosensitive glass. As a result, fine processing can be applied to the photosensitive glass, without using the mechanical processing. Further, by applying the heat treatment to the photosensitive glass at a higher temperature than the heat treatment temperature during exposure, it is possible to obtain a crystallized photosensitive glass in which a fine crystal is precipitated in the photosensitive glass. Such a crystallized photosensitive glass is excellent in a mechanical performance and a chemical durability.

The exposure of the photosensitive glass is performed using a photomask similarly to a semiconductor device manufacturing process. Specifically, UV-ray as an exposure light enters into the photomask, so that the UV-ray enters into a photosensitive glass only from an opening part having no light shielding film formed thereon, namely, only from a portion provided corresponding to a portion to be subjected to fine processing. Then, due to an energy of the UV-ray, electrons are released from a sensitizing component (CeO₂, etc.), and these electrons are captured by ions of photosensitive components (Au, Ag, and Cu, etc.), to thereby cause an oxidation-reduction reaction to occur. As a result, metal of the photosensitive component is generated in the photosensitive glass, to form a latent image (for example, see patent document 1). In other words, the photosensitive glass is indirectly irradiated with the UV-ray through the photomask, to form the latent image.

### PRIOR ART DOCUMENT

### Patent Document

Patent document 1: International Publication No. 2005/034594

### SUMMARY OF THE INVENTION

### Problem to be Solved by the Invention

The photosensitive glass (including a crystallized photosensitive glass) has an excellent mechanical performance as a glass, and fine processing can be applied thereto inexpensively. Therefore, application of the photosensitive glass is started, for an interposer in which an inexpensive Si wafer has been conventionally used, and a gas electron amplifying substrate, etc., in which resin such as polyimide having a low mechanical performance has been conventionally used.

In recent years, in the abovementioned application, a larger substrate size and a finer through holes are requested, and with this request, there is a further request for an accuracy of the fine processing performed to a formation position, etc., of the through holes.

However, a dimension of the photosensitive glass is varied, which is caused by a heat treatment at a high temperature. Particularly, in a case of obtaining the crystallized photosensitive glass with fine crystals precipitated in the photosensitive glass by heat treatment, after fine processing such as a formation of the through holes, etc., is performed, this process involves a crystallization of the photosensitive glass, and therefore a dimensional variation becomes relatively large. Specifically, the crystallized photosensitive glass shrinks by about 1.1%, compared with the photosensitive glass before applying fine processing thereto.

When a through hole having a size of about several ten μm is formed on the photosensitive glass using a photomask, heat treatment is applied to the photosensitive glass after formation of a pattern by the photomask. Accordingly, unless patterning is performed in consideration of the dimensional variation during formation of the pattern by the photomask, the formation position of the through holes is significantly deviated from a prescribed formation position, because the dimensional variation caused by the heat treatment performed thereafter is significantly larger than a diameter of the through hole. Particularly, such a problem becomes remarkable, because the dimensional variation of a substrate becomes large as a substrate size becomes large.

When the photomask is used, in order to improve an accuracy of patterning, a technique called step-and-repeat is performed, and by this technique, a prescribed correction is performed to the photomask. In the step-and-repeat, the whole part of the pattern is not formed at once, but formation of a part of the pattern is repeated using the photomask of a repeating unit which is a part of the formed pattern, so that the whole body of the pattern is formed. Accordingly, the accuracy of the whole body of the pattern can be improved only by performing a prescribed correction to the photomask.

However, the dimensional variation is different between a center part and an outer peripheral part of the photosensitive glass substrate. Therefore, when the formation position of the through holes is corrected in the step-and-repeat, a correction amount is different if a repeat position is different, and therefore a plurality of photomasks with different correction amounts are required, and this is not practical.

In view of the abovementioned circumstance, the present invention is provided, and an object of the present invention is to provide a method of easily improving the accuracy of the fine processing such as formation of the through holes, by directly correcting an irradiation position of an energy beam, in consideration of the dimensional variation of the photosensitive glass caused by heat treatment.

### Means for Solving the Problem

It is found by the inventors of the present invention, that although the dimensional variation of the photosensitive glass caused by heat treatment is large and is different depending on a place of the photosensitive glass, the dimensional variation in each photosensitive glass is small, and this is the variation of not affecting an error of the formation position of the through holes. As a result, it is also found that setting of the correction amount can be simplified.

Then, it is also found by the inventors of the present invention, that when the position accuracy of the fine processing is corrected for the photosensitive glass substrate, not by performing correction through the photomask, but directly correcting the position scheduled to be subjected to fine processing on the photosensitive glass substrate, the abovementioned problem can be solved, and thus the present invention is completed.

Namely, according to an aspect of the present invention, there is provided a method of manufacturing a photosensitive glass substrate, including:

directly irradiating a plate-like base material composed of a photosensitive glass with an energy beam to form a latent image;

crystallizing the latent image by a first heat treatment to obtain a crystallized portion; and

dissolving and removing the crystallized portion and applying fine processing thereto, to obtain a photosensitive glass substrate.

wherein in the irradiating, an irradiation position of the energy beam is corrected based on a dimensional variation of the photosensitive glass caused by a heat treatment including at least the first heat treatment.

In the abovementioned aspect, preferably the heat treatment includes a second heat treatment performed to the photosensitive glass substrate after the fine processing.

In the abovementioned aspect, preferably at a prescribed point on the photosensitive glass substrate, a correction amount calculated based on the dimensional variation is within a range of 0 to 0.3% of a distance between a center point of the photosensitive glass substrate and the prescribed point before the heat treatment, or preferably the correction amount is in a range of 0 to −2% of the distance between the center point of the photosensitive glass substrate and the prescribed point before the heat treatment, wherein the center point of the photosensitive glass substrate is a gravity center of the photosensitive glass substrate.

In the abovementioned aspect, preferably the fine processing is a step of forming through holes by dissolving and removing the crystallized portion, wherein a size of the photosensitive glass substrate is 100 mm or more and a size of each through hole is 100 μm or less.

### Advantage of the Invention

According to the present invention, there is provided a method of easily improving an accuracy of fine processing such as a formation of through holes, by directly correcting an irradiation position of an energy beam, in consideration of a dimensional variation of a photosensitive glass caused by a heat treatment.

### BRIEF DESCRIPTION OF THE DRAWINGS

FIG. 1 is a schematic view showing the manufacturing steps of a photosensitive glass substrate in a manufacturing method according to an embodiment.

FIG. 2 is a schematic view showing an example of a method of measuring a dimensional variation of the photosensitive glass substrate caused by the heat treatment, in the manufacturing method according to an embodiment.

FIG. 3 is an expanded view of III portion in FIG. 2, and a schematic view showing a reference mark formed on the photosensitive glass substrate before heat treatment, and a reference mark formed on the photosensitive glass substrate after heat treatment.

FIG. 4 is a schematic graph showing a relation between a distance from an original point in X-direction of the photosensitive glass substrate and a dimensional variation shown in FIG. 2.

### DETAILED DESCRIPTION OF THE INVENTION

The present invention will be described hereafter in detail in the following order, based on an embodiment shown in the figure.

1. Photosensitive glass substrate
2. Method of manufacturing a photosensitive glass substrate
3. Effect of this embodiment
4. Modified example, etc.

### 1. Photosensitive Glass Substrate

A photosensitive glass substrate is not particularly limited, if it is composed of a photosensitive glass. In this embodiment, the photosensitive glass substrate has a plate shape, and may be a circular plate shape, or may be a rectangular shape such as an oblong or a square, etc., according to an application.

Although the size of the photosensitive glass substrate is not particularly limited, an effect of the present invention is remarkably exhibited when the size of the photosensitive glass substrate is 100 mm or more. In the present invention, the size of the photosensitive glass molding shows a diameter when the photosensitive glass molding has a circular plate shape, and shows a length of a side when the photosensitive glass molding has a rectangular plate shape. A thickness of the photosensitive glass substrate may be determined according to the photosensitive glass substrate, and for example set to about 0.1 to 1 mm.

Further, a plurality of through holes are formed so as to be arranged on the photosensitive glass substrate regularly on a main surface of the substrate. Although the shape of each through hole is not particularly limited, usually it is a circular shape in plane view. Further, the diameter of the through hole is about 10 to 100 μm, and an arrangement pitch of the through holes is about 20 to 300 μm. In this embodiment, the photosensitive glass substrate is the substrate on which extremely lots of (several thousands to several millions) fine through holes are formed. A method of forming the through holes will be described later.

In this embodiment, the photosensitive glass is the glass containing Au, Ag, and Cu as photosensitive components in SiO₂—Li₂O—Al₂O₃-based glass, and further containing therein CeO₂ as a sensitizing component, and more specifically, for example this is the composition containing SiO₂: 55 to 85 mass %, Al₂O₃: 2 to 20 mass %, Li₂O: 5 to 15 mass %, SiO₂, Al₂O₃ and Li₂O: 85 mass % or more in total based on an entire body of the photosensitive glass, and Au: 0.001 to 0.05 mass %, Ag: 0.001 to 0.5 mass %, Cu₂O: 0.001 to 1 mass % as photosensitive components, and further CeO₂: 0.001 to 0.2 mass % as sensitizing components. The content of the photosensitive component and the sensitizing component may be determined according to a sensitivity, etc., to the energy beam used in the irradiation step described later.

As such a photosensitive glass, PEG3 by HOYA Corporation, and PEG3C by HOYA Corporation which is obtained by crystallizing the PEG3 can be given for example.

### 2. Method of Manufacturing a Photosensitive Glass Substrate

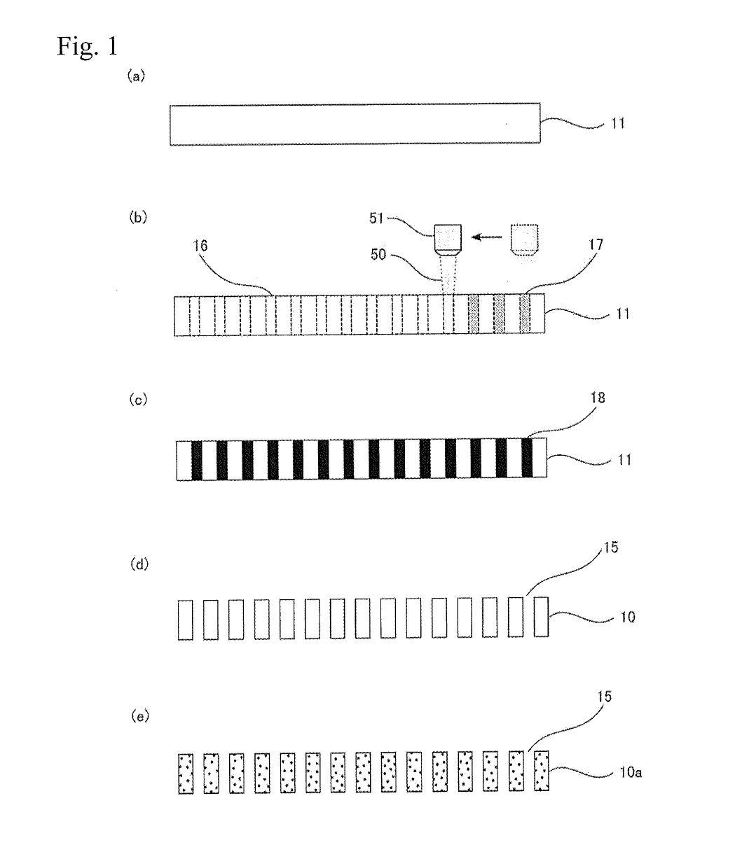

In this embodiment, the abovementioned photosensitive glass substrate is manufactured by forming a latent image on a base material composed of the photosensitive glass and crystallizing the latent image and thereafter dissolving and removing the latent image, to form the through holes. A specific method will be described using FIG. 1.

First, as shown in FIG. 1(a), a base material 11 composed of the photosensitive glass is prepared. The abovementioned glass may be used as the photosensitive glass.

### (Irradiation Step)

Next, as shown in FIG. 1(b), in the irradiation step, a latent image 17 is formed on the base material 11, at a portion to be a through hole (referred to as a through hole formation scheduled portion 16 hereafter). The latent image 17 is formed by directly irradiating the base material 11 with an energy beam 50 from an irradiation source 51 not through a photomask. Namely, as shown in FIG. 1(b), the latent image 17 is formed by sequentially irradiating the through hole formation scheduled portion 16 with the energy beam 50, while controlling the energy beam irradiation source 51 by a publicly-known moving mechanism not shown.

Irradiation conditions such as a beam diameter, the number of shots, and an aperture diameter of the energy beam 50 during irradiation may be suitably determined according to the through hold to be formed. Further, irradiation of the energy beam 50 may be performed while performing position control (for example, XY direction control) of a stage (not shown) on which the base material 11 is placed, instead of moving the irradiation source 51.

At this time, an irradiation position of the energy beam 50 is corrected based on a dimensional variation of the photosensitive glass caused by a heat treatment described later. A specific correction method will be described later.

The energy beam 50 is not particularly limited, but the following energy beam 50 is preferable. That is, it is preferable to use the beam that allows an oxidation reduction reaction to occur between the photosensitive component and the sensitizing component in the photosensitive glass, and having an energy of sufficiently generating a metal of the photosensitive component. It is also preferable to use the beam whose diameter can be narrowed so that the latent image 17 can be formed corresponding to a diameter of the through hole to be formed.

In this embodiment, a laser beam is used as the energy beam. This is because the laser beam has a high directivity, and a high energy density can be realized by further narrowing the beam diameter. As a specific laser beam, UV laser beam and an excimer laser beam, etc., can be given for example.

### (Crystallization Step)

Subsequently, a first heat treatment is applied to the base material on which the latent image is formed. The first heat treatment is the treatment performed for making the latent image as a crystallized portion. In the irradiation step, the metal of the photosensitive component generated by the oxidation reduction reaction between the photosensitive component (such as Au) and the sensitizing component (such as Ce) is present in the latent image formed by irradiation of the laser beam.

By performing the first heat treatment, as shown in FIG. 1(c), the metal is agglomerated to form a colloide in the latent image 17, and further a crystal of Li₂O—SiO₂ (lithium monosilicate) is precipitated, with the colloid as a crystal nucleus, to thereby form a crystallized portion 18. Accordingly, the crystallized portion 18 is formed at a position corresponding to the through hole formation scheduled portion 16, similarly to the latent image 17.

In the first heat treatment, formation of the colloid is started when heat is increased to 400° C., and the crystallization is advanced to finally reach a temperature in a range of 500 to 600° C. The holding time is not particularly limited, and may be set so that the crystal of monosilicate is sufficiently precipitated and its crystal size is not excessively large. This is because when the size of the crystal is excessively large, accuracy of the fine processing by etching described later, is deteriorated. In the first heat treatment, the photosensitive glass is softened at a temperature in the vicinity of 515° C.

### (Through Hole Formation Step)

In the through hole formation step, as shown in FIG. 1(d), the formed crystallized portion 18 is dissolved and removed by etching using HF (hydrogen fluoride), to form through holes 15. The crystallized portion 18, namely, lithium monosilicate is easily dissolved in the hydrogen fluoride, compared to a non-crystallized glass portion. Specifically, a difference of a dissolving rate between the crystallized portion 18 and the glass portion other than the crystallized portion, is about 50 times. Accordingly, by using the difference of the dissolving rate and using the hydrogen fluoride as an etching solution, and for example spraying the hydrogen fluoride against both surfaces of the base material 11 by spray etching not shown, the crystallized portion 18 is dissolved and removed, to form the through holes 15. That is, by performing selective etching to the base material 11, the through holes 15 can be formed.

### (Photosensitive Glass Modifying Step)

In this embodiment, a second heat treatment is applied to the photosensitive glass substrate 10 on which the through holes 15 are formed, to thereby modify the photosensitive glass. Specifically, the second heat treatment is performed at a higher temperature than the first heat treatment, for example, in a temperature range of about 800 to 1200° C. By this second heat treatment, as shown in FIG. 1(e), the crystal of the lithium disilicate is precipitated over the entire body of the photosensitive glass, and the photosensitive glass is modified, to thereby form a crystallized photosensitive glass substrate 10a. The crystallized photosensitive glass has more excellent mechanical performance and chemical durability than a non-modified photosensitive glass. The crystallized photosensitive glass is simply called a photosensitive glass hereafter.

The obtained photosensitive glass substrate is used for the abovementioned application. At this time, each through hole is filled with a conductive metal as needed.

### (Correction of the Irradiation Position in the Irradiation Step)

As described above, exposure to the photosensitive glass substrate is frequently performed through the photomask having a mask pattern corresponding to a pattern to be exposed (for example, the through hole formation scheduled portion). However, in the exposure through the photomask, particularly a substrate size becomes large, and when patterning (formation of the through holes) becomes finer, there is a new problem that an accuracy of patterning (for example, deviation of the formation position of the through holes) is deteriorated. Such a problem is the problem caused by a performance specific to the photosensitive glass.

A dimensional variation that occurs by the heat treatment applied to the photosensitive glass can be given as the performance specific to the photosensitive glass. When the photosensitive glass substrate is manufactured, a volume variation occurs in the photosensitive glass substrate, which is caused by the precipitation of a new crystal, and a change, etc., of a structure from a non-crystallized state to a crystallized state, by passing through the abovementioned heat treatment. Therefore, the dimensional variation occurs in the photosensitive glass substrate.

When a specific dimensional variation is given for example, a shrinkage of up to about 1.1% of the substrate size occurs by the first heat treatment and the second heat treatment described above, relative to the substrate size before the heat treatment. Accordingly, for example, when a size of one side in a planar direction of the substrate, that is, when the diameter of the substrate is about 300 mm, an outer peripheral part of the substrate shrinks by about 3.3 mm in the planar direction after the first heat treatment and the second heat treatment. Such a shrinkage (dimensional variation) is different depending on the place of the substrate, and does not occur in a center part and is likely to be large toward an outer peripheral part of the substrate.

On the other hand, the diameter of through hole formed on the photosensitive glass substrate is about several ten μm, and its arrangement pitch is about several ten to several hundred μm. However, in order to exhibit a prescribed performance of the substrate, the through holes are required to be accurately formed at a prescribed position of the photosensitive glass substrate after the heat treatment (first heat treatment and second heat treatment). Accordingly, high accuracy of the formation position of the through holes is requested, despite the abovementioned significantly large dimensional variation of the diameters of the through holes. Specifically, an error range (accuracy) of the formation position of the through holes is about 10 to 25 μm, although depending on the diameter of the through holes.

It can be easily understood that such a deviation of the formation position becomes remarkable, as the size of the photosensitive glass substrate becomes large (namely, the dimensional variation becomes large), and as the diameter or the arrangement of the through holes 15 becomes finer (namely, a position accuracy of the arrangement becomes more strict).

As described above, the position of the through hole formation scheduled portion on the photosensitive glass substrate before the heat treatment, is required to be corrected in consideration of the dimensional variation of the photosensitive glass substrate after the heat treatment, so that the deviation (error) of the formation position of the through holes is in the abovementioned range.

Incidentally, when the exposure is performed using the photomask, the heat treatment is performed after removing the photomask after formation of the pattern. Therefore, the through hole on the through hole formation scheduled portion formed using the photomask, are deviated from the formation scheduled position, due to the dimensional variation of the photosensitive glass substrate which is caused by the heat treatment.

Accordingly, the mask pattern of the photomask is required to be the mask pattern reflecting the dimensional variation of the photosensitive glass substrate. In this case, it is conceivable that a pattern exposure is performed while correcting the position by the step and repeat.

The correction in the step and repeat is performed to a part (repeating unit) of the pattern formed on the substrate, by forming the entire pattern by repeating formation of the pattern, using the photomask having the mask pattern reflecting the prescribed correction. That is, by adding a fine adjustment to the mask pattern of the photomask, an exposure position is indirectly corrected.

However, in this embodiment, a patterning object, namely, the dimension of the photosensitive glass substrate itself is changed, and the dimensional variation is different between the outer peripheral part and the center part. This means that when a repeat position is changed, the dimensional variation is also changed in the step and repeat. Therefore, in order to correct the formation position of the through holes, a plurality of photomasks corresponding to the dimensional variation is required to be fabricated, and this is not practical in terms of a cost, etc.

In such a circumstance, regarding the dimensional variation of the photosensitive glass substrate, a significantly important fact is found by the inventors of the present invention. The fact is that the dimensional variation itself of the photosensitive glass caused by the heat treatment is large to have an influence on the accuracy of the formation position of the fine through holes, but the difference of the dimensional variation generated for each photosensitive glass substrate is small when the heat treatment is applied to the photosensitive glass substrate having the same composition under the same condition, that is, the dimensional variation is small. In other words, the same kind of dimensional variation occurs in any kind of the substrate by the heat treatment.

Specifically, it is found by the inventors of the present invention, that the dimensional variation that appears in the substrate with a size of 300 mm and having the same composition when the heat treatment is applied thereto under the same condition, is about ±10 μm after the first heat treatment and the second heat treatment are performed, and is significantly small compared to the dimensional variation itself.

On the other hand, by setting the variation in the abovementioned range, it is conceivable that the variation does not have a so much influence on the position accuracy required for the formation position of the through holes when the variation is in the abovementioned range, in consideration of the fact that an error range (patterning accuracy) required for the formation position of the through holes is about 10 to 25 μm. Therefore, it is not always necessary to set a correction amount for each substrate based on the dimensional variation, and the correction amount set for one of the substrates can be applied to the other substrate. That is, setting of the correction amount can be simplified.

Therefore, in this embodiment, the correction of the irradiation position in the irradiation step, is performed according to the dimensional variation of the photosensitive glass caused by the first heat treatment in the crystallization step, and the second heat treatment in the photosensitive glass modifying step.

Further, as described above, it is difficult to perform correction using the photomask, and therefore in this embodiment, as described in the irradiation step, an operation of forming the latent image on the photosensitive glass, is performed by directly irradiating the position corrected by reflecting the dimensional variation, with the energy beam such as a laser beam, etc. By irradiating the corrected position (different position from the initial formation position) with the energy beam, the beam irradiation position is corrected previously in consideration of the dimensional variation even if the dimensional variation occurs in the photosensitive glass substrate which is caused by the heat treatment performed thereafter, and therefore there is no deviation in the fine-shaped patterning (for example, the formation position of the through holes) after the heat treatment.

The correction amount is specifically set using a publicly-known method, and in this embodiment, the correction amount is calculated from a relation between a distance from an original point and the dimensional variation, with a center of the substrate as the original point. Then, the calculated correction amount is added to an initial value of a coordinate of the through hole formation scheduled portion which is set without considering the dimensional variation, to thereby correct the position irradiated with the energy beam. A specific explanation will be given hereafter.

In this embodiment, the heat treatment is applied to the photosensitive glass substrate for measuring the dimensional variation, then the dimensional variation of the substrate is measured, and based on the obtained dimensional variation, the correction amount is set. Only the first heat treatment may be used, or both of the first heat treatment and the second heat treatment may be used as the heat treatment. The set correction amount is added to the coordinate (position) of the through hole formation scheduled portion on the photosensitive glass substrate on which the through holes are formed. In addition, by using the substrate in which a prescribed through hole formation scheduled portion is exposed, or the substrate on which the prescribed through holes are formed, as the substrate for measuring the dimensional variation, the accuracy of the position for forming the through holes can be more increased. Also, by using a plurality of substrates for measuring the dimensional variation, the correction amount can be more suitably set, and the accuracy of the position for forming the through holes can be more increased.

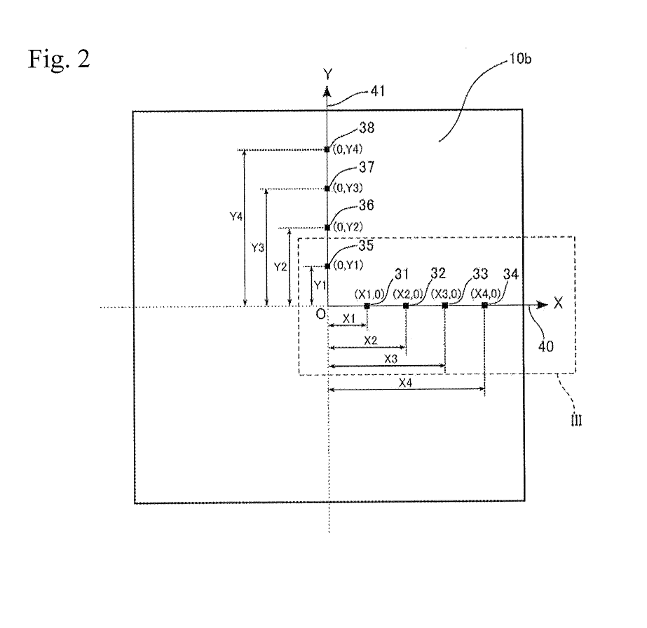

First, as shown in FIG. 2, detectable reference marks 31 to 38 are assigned to the photosensitive glass substrate 10b for measuring the dimensional variation before the heat treatment. The reference marks 31 to 38 are assigned for detecting the dimensional variation of the photosensitive glass substrate 10b. Further, as shown in FIG. 2, two virtual reference lines 40 and 41 are set so as to pass through a center point O of the photosensitive glass substrate 10b, so that a virtual reference line 40 is set in X-direction, and a virtual reference line 41 is set in Y-direction. Reference marks 31 to 34 are arranged in the X-direction, and reference marks 35 to 38 are arranged in the Y-direction. These reference marks 31 to 38 are arranged so that the distance from the center point O is a prescribe distance (X1, X2, . . . , Y1, Y2, . . . ).

In this embodiment, the center point O of the photosensitive glass substrate 10b is a gravity center of the photosensitive glass substrate 10b. That is, as shown in FIG. 2, when the photosensitive glass substrate 10b has a square shape, the center point O of the photosensitive glass substrate 10b is an intersection of diagonal lines. Also, when the photosensitive glass substrate has a circular shape, the center point O of the photosensitive glass substrate 10b is the center of a circle.

There is no particular limit when the reference marks 31 to 38 are arranged so as to detect the dimensional variation amount, and for example, an alignment mark used of other application may be diverted.

Subsequently, after applying the heat treatment to the photosensitive glass substrate 10b (photosensitive glass substrate for measuring the dimensional variation) on which reference marks 31 to 38 are formed, positions of the reference marks 31 to 38 are detected to thereby calculate the dimensional variation.

In the following explanation, explanation will be given for a case of setting the correction amount in the X-direction, by focusing on the reference marks 31 to 34 arranged in the X-direction. The same can be applied to the Y-direction.

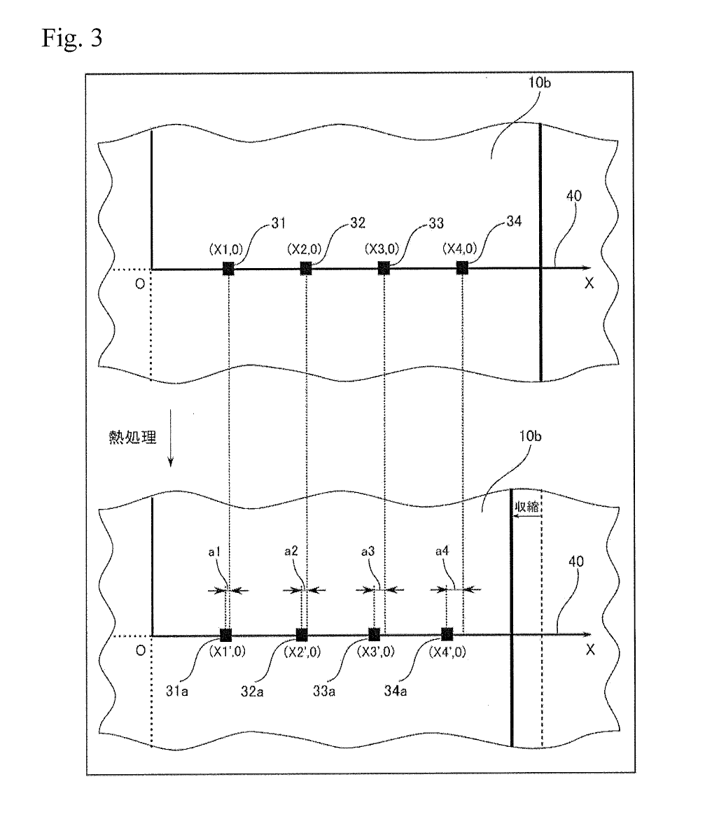

As shown in FIG. 3, regarding the reference marks 31 to 34, the distance from the center point O, that is, the positions of the reference marks 31a to 34a are detected by the publicly-known technique on the photosensitive glass substrate 10b after the heat treatment, to thereby calculate the distance (coordinate) between the center point O and each reference mark, because the coordinate is already known.

The method of detecting the reference marks 31 to 38 is not particularly limited, when this is the method of surely detecting the formed marks, and a publicly-known detection method may be suitably used. Also, the coordinate of each reference mark may be calculated using a publicly-known image processing technique.

In FIG. 3, the distance between the center point O and the reference mark 31a is indicated by X1′, and the distance between the center point O and the reference mark 32a is indicated by X2′, and the distance between the center point O and the reference mark 33a is indicated by X3′, and the distance between the center point O and the reference mark 34a is indicated by X4′.

Subsequently, by comparing the obtained distances X1′, X2′, X3′, and X4′, and the distance between the center point O and each reference mark on the photosensitive glass substrate 10b before the heat treatment, that is, X1, X2, X3, X4, the dimensional variation at each reference mark in the X-direction on the photosensitive glass substrate is calculated.

Namely, as shown in FIG. 3, when the center point O is set as the original point of an orthogonal coordinate constituted of the virtual reference lines, the dimensional variation at X1 is indicated by (X1′-X1) (=a1), the dimensional variation at X2 is indicated by (X2′, −X2) (=a2), the dimensional variation at X3 is indicated by (X3′, −X3) (=a3), and the dimensional variation at X4 is indicated by (X4′, −X4) (=a4), in the X-direction.

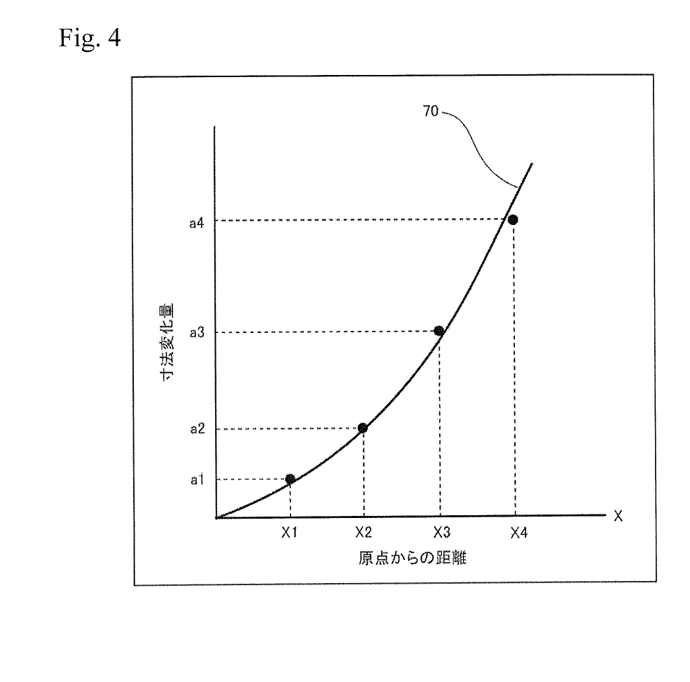

Then, based on the calculated dimensional variation, as shown in FIG. 4, function 70 showing a relation between the distance (X1 to X4) from the original point, and the dimensional variation (a1 to a4) is calculated. A publicly-known method may be used as a calculation method of the function, and for example, a least square method may be used. Regarding the Y-direction also, the function showing the relation between the distance from the original point and the dimensional variation is calculated.

Next, the correction amount is calculated by substituting the coordinate (position) of each through hole formation scheduled portion, to the obtained function. Then, the calculated correction amount is added to the coordinate of the through hole formation scheduled portion not in consideration of the dimensional variation. For example, when the coordinate of the center point of the through hole at the formation scheduled portion on the photosensitive glass substrate before the heat treatment is (X1, Y1), and the calculated correction amount in the X-direction is a1, and the calculated correction amount in the Y-direction is b1, the coordinate at the center point of the through hole after correction is (X1+a1, Y1+b1), and the energy beam is emitted, with this coordinate as a center position. Further, regarding the diameter of the through hole as well, the beam diameter during irradiation is controlled so as to form the latent image having a diameter reflecting the dimensional variation.

That is, the irradiation position of the energy beam in the irradiation step is corrected, to make a coordinate (X1+a, Y1+b), and a beam diameter during irradiation is set to be a diameter reflecting the correction amount based on the dimensional variation, for the diameter of the through hole which is scheduled to be formed.

Then, the corrected irradiation position is directly irradiated with the energy beam. As a result, even if the dimensional variation occurs in the photosensitive glass due to the heat treatment, the dimensional variation is canceled by the correction amount. Accordingly, regarding the through hole on the photosensitive glass substrate which is finally obtained after the heat treatment, the deviation of the prescribed formation scheduled position, that is, the deviation of the position formed on the coordinate (X1, Y1) for forming the through hole, can be effectively suppressed.

In this embodiment, the correction amount at the prescribed through hole scheduled position on the photosensitive glass substrate, is in a range of 0 to −2% of the distance between the center point of the photosensitive glass substrate, and the prescribed through hole scheduled position before the heat treatment.

A method of setting the correction amount is not limited to the abovementioned method, and the correction amount may be determined using other method.

### 3. Effect of this Embodiment

Due to a large dimensional variation of the photosensitive glass caused by the heat treatment, there is a problem in terms of a processing accuracy when fine processing (such as formation of fine through holes) is applied to the substrate. Specifically, when the through holes are formed on the substrate, a deviation is easily generated between an actual formation position and a prescribed formation scheduled position of the through holes.

Therefore, in this embodiment, a correction amount based on the dimensional variation of the photosensitive glass substrate is reflected on an irradiation position of the energy beam without using a mask. Thus, the deviation of the formation position of the through holes can be effectively suppressed. Accordingly, in a case of the method of this embodiment, a patterning can be performed with high accuracy even when a fine patterning is performed.

In addition, not the correction by the mask pattern, but a direct correction of the irradiation position itself of the energy beam, is performed. Therefore, if the correction amount can be determined, the correction reflecting this correction amount can be easily performed. Further, this correction amount can be easily and accurately set, with no necessity for setting it for each substrate, because the dimensional variation of the photosensitive glass substrate is small.

Such an effect becomes remarkable when the size of the substrate is 100 mm or more, and the diameter of the through hole is 100 μm or less. This is because the dimensional variation of the photosensitive glass substrate is significantly large relatively to an accuracy of the formation position of the through holes.

Further, by setting the correction amount in the abovementioned range relatively to a distance between the center point of the substrate and the formation position of the through holes, the accuracy of the formation position of the through holes can be easily improved.

Therefore, according to this embodiment, high accuracy of the fine patterning (suppression of the deviation of the formation position) can be easily realized. That is, since the dimensional variation of the photosensitive glass substrate is small, the correction amount can be easily and accurately calculated, and in addition, since the photosensitive glass substrate is directly irradiated with the energy beam, the correction amount can be reflected on the actual irradiation position.

### 4. Modified Example, Etc.

In the abovementioned embodiment, explanation is given for the crystallized photosensitive glass substrate obtained by modifying the photosensitive glass substrate having the through holes formed thereon, by the second heat treatment. However, regarding the photosensitive glass substrate not subjected to the second heat treatment as well, the irradiation position can be similarly corrected.

When the first heat treatment, that is, only the heat treatment in the crystallization step, is performed to the photosensitive glass substrate, the size of the substrate is expanded by about 0.1% from the size before the heat treatment. That is, when the size of the substrate is about 300 mm, the substrate is expanded by about 0.3 mm in the plane direction. Further, the dimensional variation is about ±5

The correction amount at a prescribed through hole formation scheduled position on the photosensitive glass substrate, is within a range of 0 to 0.3% of the distance between the center point of the photosensitive glass substrate and the prescribed through hole formation scheduled position before the heat treatment.

Accordingly, by setting the correction amount based on the abovementioned dimensional variation and correcting the irradiation position, the accuracy of the formation position of the through holes can be improved similarly to the abovementioned embodiment.

Further, in the abovementioned embodiment, the correction amount is set from the relation between the center point O of the photosensitive glass substrate and the dimensional variation. However, the correction amount may be set by other method. For example, the heat treatment is applied to a plurality of substrates for measuring the dimensional variation, and the deviation (dimensional variation) in a prescribed coordinate on each substrate is calculated, and its average value may be set as the correction amount.

Further, in the abovementioned embodiment, the formation of the through holes is performed as the fine processing to the base material composed of the photosensitive glass. However, other fine processing may be performed. For example, the formation of the latent image is performed up to a middle of the base material, and a bottomed hole may be formed.

As described above, the embodiments of the present invention have been described. However, the present invention is not limited to the abovementioned embodiments, and can be variously modified in a range not departing from the gist of the present invention.

### DESCRIPTION OF SIGNS AND NUMERALS

10, 10a, 10b Photosensitive glass substrate
11 Base material
15 Through hole
16 Through hole formation scheduled portion
17 Latent image
18 Crystallized portion
31 to 38 Reference mark
50 Energy beam

1. A method of manufacturing a photosensitive glass substrate, comprising:
directly irradiating a plate-like base material composed of a photosensitive glass with an energy beam to form a latent image;
crystallizing the latent image by a first heat treatment to obtain a crystallized portion; and
dissolving and removing the crystallized portion and applying fine processing thereto, to obtain a photosensitive glass substrate.
wherein in the irradiating, an irradiation position of the energy beam is corrected based on a dimensional variation of the photosensitive glass caused by a heat treatment including at least the first heat treatment.

2. The method of manufacturing a photosensitive glass substrate according to claim 1, wherein the heat treatment includes a second heat treatment performed to the photosensitive glass substrate after the fine processing.

3. The method of manufacturing a photosensitive glass substrate according to claim 1, wherein at a prescribed point on the photosensitive glass substrate, a correction amount calculated based on the dimensional variation is within a range of 0 to 0.3% of a distance between a center point of the photosensitive glass substrate and the prescribed point before the heat treatment, wherein the center point of the photosensitive glass substrate is a gravity center of the photosensitive glass substrate.

4. The method of manufacturing a photosensitive glass substrate according to claim 2, wherein at a prescribed point on the photosensitive glass substrate, the correction amount is in a range of 0 to −2% of the distance between the center point of the photosensitive glass substrate and the prescribed point before the heat treatment, and the center point of the photosensitive glass substrate is a gravity center of the photosensitive glass substrate.

5. The method of manufacturing a photosensitive glass substrate according to claim 1, wherein the fine processing is a step of forming through holes by dissolving and removing the crystallized portion, and a size of the photosensitive glass substrate is 100 mm or more and a size of each through hole is 100 μm or less.

6. The method of manufacturing a photosensitive glass substrate according to claim 2, wherein the fine processing is a step of forming through holes by dissolving and removing the crystallized portion, and a size of the photosensitive glass substrate is 100 mm or more and a size of each through hole is 100 μm or less.

7. The method of manufacturing a photosensitive glass substrate according to claim 3, wherein the fine processing is a step of forming through holes by dissolving and removing the crystallized portion, and a size of the photosensitive glass substrate is 100 mm or more and a size of each through hole is 100 μm or less.

8. The method of manufacturing a photosensitive glass substrate according to claim 4, wherein the fine processing is a step of forming through holes by dissolving and removing the crystallized portion, and a size of the photosensitive glass substrate is 100 mm or more and a size of each through hole is 100 μm or less.
